(19) United States
(12) Patent Application Publication
(10) Pub. No.: US 2011/0216920 A1
(43) Pub. Date: Sep. 8, 2011

(54) SPEAKER DRIVE INTEGRATED CIRCUIT

(76) Inventors: Makoto Yamamoto, Kanagawa (JP); Yasuo Higuchi, Kanagawa (JP); Satoshi Azuhata, Kanagawa (JP)

(21) Appl. No.: 13/033,929

(22) Filed: Feb. 24, 2011

(30) Foreign Application Priority Data
Mar. 2, 2010 (JP) 2010-045797

(51) Int. Cl. H03F 99/00

(52) U.S. Cl. 381/120

(57) ABSTRACT

A speaker drive integrated circuit of the present invention includes: a load connection status detecting circuit configured to cause a current to flow from an external power supply to one of output terminals when an output side of an amplifying circuit is set to a high impedance state and detect whether a load connection status is normal, open, or short based on a voltage generated at the output terminal; and a transmitting terminal through which a signal indicating a detection result by the load connection status detecting circuit is output to outside.

### RELATED APPLICATIONS

The disclosure of Japanese Patent Application No. 2010-045797 filed on Mar. 2, 2010 including specification, drawings and claims is incorporated herein by reference in its entirety.

### BACKGROUND OF THE INVENTION

1. Field of the Invention

The present invention relates to a speaker drive integrated circuit.

2. Description of the Related Art

Each of mobile devices, such as digital video cameras, digital still cameras, mobile phones, notebook computers, and fire alarms, normally includes a thin, light-weight speaker (such as a piezoelectric speaker). A power supply, such as a recently mainstream lithium ion battery, is used to drive the mobile device. However, to realize the emission of a sound having an adequate sound pressure level from the speaker, a switching power supply circuit capable of generating a higher voltage than the power supply is required.

For example, Japanese Laid-Open Patent Application Publication No. 1988-217806 discloses that as shown in FIG. 7, a speaker drive amplifier 202 configured to drive a ceramic speaker 201 includes: a switching power supply circuit 209 configured to boost a voltage to generate a voltage higher than a voltage of an external IC power supply (low voltage power supply) 210; and an amplifying circuit 208 configured to output a signal obtained by amplifying an input audio signal to the ceramic speaker 201 based on the high voltage boosted and generated by the switching power supply circuit 209.

To reduce the size and weight of the mobile device on which the conventional speaker drive integrated circuit is mounted, the switching power supply circuit and the amplifying circuit are integrated in one IC (Integrated Circuit) as with the speaker drive amplifier 202 described in Japanese Laid-Open Patent Application Publication No. 1988-217806.

### SUMMARY OF THE INVENTION

In the conventional speaker drive integrated circuit, a unit configured to detect whether the connection between the speaker drive integrated circuit and the speaker is open (not connected) or shorted (short-circuited) and transmit such load connection status to the outside is not provided. Therefore, the problem is that if the sound is not emitted from the speaker, a user cannot easily recognize whether there is a problem with the connection between the speaker drive integrated circuit and the speaker or with the inside of the speaker drive integrated circuit.

Here, an object of the present invention is to appropriately mount on a speaker drive integrated circuit a circuit configured to detect whether the connection status of the speaker is normal, open, or short.

To solve the above problem, a speaker drive integrated circuit according to the present invention includes: a power supply terminal and a GND terminal, each connected to an external power supply; an input terminal to which an audio signal is input; two output terminals respectively connected to both ends of a speaker; an amplifying circuit including a first amplifier and a second amplifier and capable of setting an output side thereof to a high impedance state during a non-operating period, the first amplifier being configured to amplify the audio signal input to the input terminal and output the amplified audio signal through one of said two output terminals, the second amplifier being configured to invert a phase of the audio signal, amplify the phase-inverted audio signal, and output the amplified audio signal through the other output terminal; a switching power supply circuit configured to boost a voltage of the external power supply connected to the power supply terminal and the GND terminal such that an output of the amplifying circuit becomes a predetermined voltage necessary for driving the speaker; a standby circuit configured to selectively set the amplifying circuit between an operating state and a nonoperating state where the output side is in the high impedance state; a load connection status detecting circuit configured to cause a current to flow from the external power supply to one of said two output terminals when the standby circuit sets the amplifying circuit to the nonoperating state where the output side is in the high impedance state and detect whether a load connection status of the speaker with respect to said two output terminals is normal, open, or short based on a voltage generated at said one of said two output terminals by the current; and a transmitting terminal through which a signal indicating a detection result by the load connection status detecting circuit is output to outside.

In accordance with this configuration, in a state where the output of the amplifying circuit is set to the high impedance state and the speaker stops operating, the external power supply for driving the speaker can be effectively utilized (the voltage for monitoring is generated by the external power supply), and the connection status (normal, open, or short) of the speaker can be detected and transmitted to the outside. Moreover, the load connection status detecting circuit for detecting the load connection status, the amplifying circuit, and the switching power supply circuit are integrated in one IC, so that the mobile device on which the load connection status detecting circuit is mounted can be reduced in size and weight.

The speaker drive integrated circuit may further include: a standby terminal to which a standby voltage is applied, the standby voltage specifying the nonoperating state of the amplifying circuit with respect to the standby circuit; and a start-up terminal to which a start-up voltage is applied, the start-up voltage causing the load connection status detecting circuit to start up, wherein when the start-up voltage is applied to the start-up terminal, the load connection status detecting circuit may cause a current to flow from the external power supply to one of said two output terminals to start detecting the load connection status.

In accordance with this configuration, since the load connection status detecting circuit can start up in accordance with the timing for detecting the load connection status, the power consumption of the entire integrated circuit when the speaker stops operating can be suppressed.

The speaker drive integrated circuit may further include: a start-up terminal to which a start-up voltage is applied, the start-up voltage causing the load connection status detecting circuit to start up, wherein when the start-up voltage is applied to the start-up terminal, the load connection status detecting circuit may set the output side of the amplifying circuit to the high impedance state and cause a current to flow from the external power supply to one of said two output terminals to start detecting the load connection status.

In accordance with this configuration, one input terminal (start-up terminal) can function as both an input terminal to which an external command (start-up voltage) for starting up the load connection status detecting circuit is input and an input terminal to which an external command (standby voltage) for setting the output of the amplifying circuit to the high impedance state is input. With this, the speaker drive integrated circuit can be further reduced in size.

In the speaker drive integrated circuit according to claim 3, the load connection status detecting circuit may include: a first transistor provided between the power supply terminal and one of said two output terminals and configured to be turned on when the start-up voltage is applied to the start-up terminal; a second transistor provided between the other output terminal and the GND terminal and configured to be turned on when the start-up voltage is applied to the start-up terminal; an open detecting comparator configured to compare a voltage of said one of said two output terminals with an open threshold voltage and detect that the load connection status is open if the voltage of said one of said two output terminals is higher than the open threshold voltage in a predetermined period after the start-up voltage is applied to the start-up terminal; and a short detecting comparator configured to compare the voltage of said one of said two output terminals with a short threshold voltage and detect that the load connection status is short if the voltage of said one of said two output terminals is lower than the short threshold voltage in the predetermined period after the start-up voltage is applied to the start-up terminal.

In accordance with this configuration, the mount area, cost, and the like can be reduced and the integration can be realized by a small number of parts, that is, two transistors (the first transistor and the second transistor) and two comparators (the open detecting comparator and the short detecting comparator). Thus, the mobile device on which the load connection status detecting circuit is mounted can be reduced in size and weight.

The speaker drive integrated circuit may further include: a first current-limiting resistor configured to limit a current when the start-up voltage is applied to the start-up terminal, the current flowing through the first transistor; a protection circuit configured to short or clamp each of inputs of the open detecting comparator and short detecting comparator to GND or a potential equal to or lower than a withstand voltage of the input when the start-up voltage is not applied to the start-up terminal, the open detecting comparator and the short detecting comparator being supplied with the voltage of said one of said two output terminals; and a second current-limiting resistor configured to limit a current when the start-up voltage is not applied to the start-up terminal, the current flowing to the inputs of the open detecting comparator and short detecting comparator.

In accordance with this configuration, when driving the speaker (when the start-up voltage is not applied), the open detecting comparator and the short detecting comparator can be appropriately protected by the protection circuit and the second current-limiting resistor. Moreover, when detecting the load connection status (when applying the start-up voltage), the first transistor can be appropriately protected by the parasitic diode of the first transistor and the first current-limiting resistor.

In the speaker drive integrated circuit, the load connection status detecting circuit may include: a current mirror circuit configured by a pair of first transistors to cause a current to flow from the switching power supply to one of said two output terminals when the start-up voltage is applied to the start-up terminal; a second transistor provided between the other output terminal and the GND terminal and configured to be turned on when the start-up voltage is applied to the start-up terminal; an open detecting comparator configured to compare a voltage of said one of said two output terminals with an open threshold voltage and detect that the load connection status is open if the voltage of said one of said two output terminals is higher than the open threshold voltage in a predetermined period after the start-up voltage is applied to the start-up terminal; and a short detecting comparator configured to compare the voltage of said one of said two output terminals with a short threshold voltage and detect that the load connection status is short if the voltage of said one of said two output terminals is lower than the short threshold voltage in the predetermined period after the start-up voltage is applied to the start-up terminal.

In accordance with this configuration, the mount area, cost, and the like can be reduced and the integration can be realized by a small number of parts, that is, the current mirror circuit, one transistor (second transistor), and two comparators (the open detecting comparator and the short detecting comparator). Thus, the mobile device on which the load connection status detecting circuit is mounted can be reduced in size and weight.

The speaker drive integrated circuit may further include: a protection circuit configured to short or clamp each of inputs of the open detecting comparator and short detecting comparator to GND or a potential equal to or lower than a withstand voltage of the input when the start-up voltage is not applied to the start-up terminal, the open detecting comparator and the short detecting comparator being supplied with the voltage of said one of said two output terminals; a first current-limiting resistor configured to limit a current when the start-up voltage is not applied to the start-up terminal, the current flowing to the inputs of the open detecting comparator and short detecting comparator; and a second current-limiting resistor configured to limit a current when the start-up voltage is applied to the start-up terminal, the current flowing through the current mirror circuit.

In accordance with this configuration, when driving the speaker (when the start-up voltage is not applied), the open detecting comparator and the short detecting comparator can be appropriately protected by the protection circuit and the second current-limiting resistor. Moreover, when detecting the load connection status (when applying the start-up voltage), the current mirror circuit can be appropriately protected by the second current-limiting resistor.

In the speaker drive integrated circuit, the load connection status detecting circuit may include: a first transistor provided between an output of the switching power supply circuit and one of said two output terminals and configured to be turned on when the start-up voltage is applied to the start-up terminal; a second transistor provided between the other output terminal and the GND terminal and configured to be turned on when the start-up voltage is applied to the start-up terminal; an open detecting comparator configured to compare a voltage of said one of said two output terminals with an open threshold voltage and detect that the load connection status is open if the voltage of said one of said two output terminals is higher than the open threshold voltage in a predetermined period after the start-up voltage is applied to the start-up terminal; and a short detecting comparator configured to compare the voltage of said one of said two output terminals with a short threshold voltage and detect that the load connection status is short if the voltage of said one of said two output terminals is lower than the short threshold voltage in the predetermined period after the start-up voltage is applied to the start-up terminal.

In accordance with this configuration, the mount area, cost, and the like can be reduced and the integration can be realized by a small number of parts, that is, two transistors (the first transistor and the second transistor) and two comparators (the open detecting comparator and the short detecting comparator). Thus, the mobile device on which the load connection status detecting circuit is mounted can be reduced in size and weight.

The speaker drive integrated circuit may further include: a first current-limiting resistor configured to limit a current when the start-up voltage is applied to the start-up terminal, the current flowing through the first transistor; a protection circuit configured to short or clamp each of inputs of the open detecting comparator and short detecting comparator to GND or a potential equal to or lower than a withstand voltage of the input when the start-up voltage is not applied to the start-up terminal, the open detecting comparator and the short detecting comparator being supplied with the voltage of said one of said two output terminals; a second current-limiting resistor configured to limit a current when the start-up voltage is not applied to the start-up terminal, the current flowing to the inputs of the open detecting comparator and short detecting comparator; and a level-shift circuit configured to carry out level shift such that a control voltage applied to a control electrode of the first transistor becomes a predetermined potential.

In accordance with this configuration, when driving the speaker (when the start-up voltage is not applied), the open detecting comparator and the short detecting comparator can be appropriately protected by the protection circuit and the second current-limiting resistor. Moreover, when detecting the load connection status (when applying the start-up voltage), the first transistor can be appropriately detected by the parasitic diode of the first transistor and the first current-limiting resistor.

In accordance with the present invention, a circuit configured to detect whether the speaker connection status is normal, open, or short can be appropriately mounted on an integrated circuit.

### BRIEF DESCRIPTION OF THE DRAWINGS

FIG. 1 is a configuration diagram showing a sound system using a speaker drive integrated circuit according to Embodiment 1 of the present invention.

FIG. 2 is a configuration diagram showing a load connection status detecting circuit in Embodiment 1 of the present invention.

FIG. 3A is a timing waveform diagram of the load connection status detecting circuit in Embodiment 1 of the present invention when a load connection status is normal.

FIG. 3B is a timing waveform diagram of the load connection status detecting circuit in Embodiment 1 of the present invention when the load connection status is open.

FIG. 3C is a timing waveform diagram of the load connection status detecting circuit in Embodiment 1 of the present invention when the load connection status is short.

FIG. 4 is a configuration diagram showing the sound system using the speaker drive integrated circuit according to Embodiment 2 of the present invention.

FIG. 5 is a configuration diagram showing the load connection status detecting circuit in Embodiment 2 of the present invention.

FIG. 6 is a configuration diagram showing the load connection status detecting circuit in Embodiment 3 of the present invention.

FIG. 7 is a configuration diagram showing a conventional speaker drive integrated circuit.

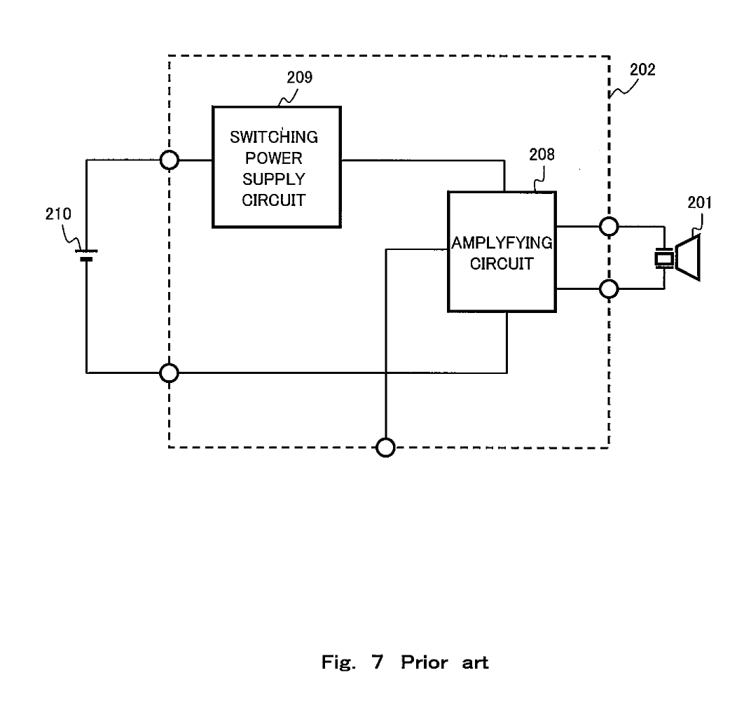

### DESCRIPTION OF THE PREFERRED EMBODIMENTS

Hereinafter, preferred embodiments of the present invention will be explained in reference to the drawings. In the drawings, the same reference signs are used for the same or corresponding components, and a repetition of the same explanation is avoided.

### Embodiment 1

Configuration of Sound System

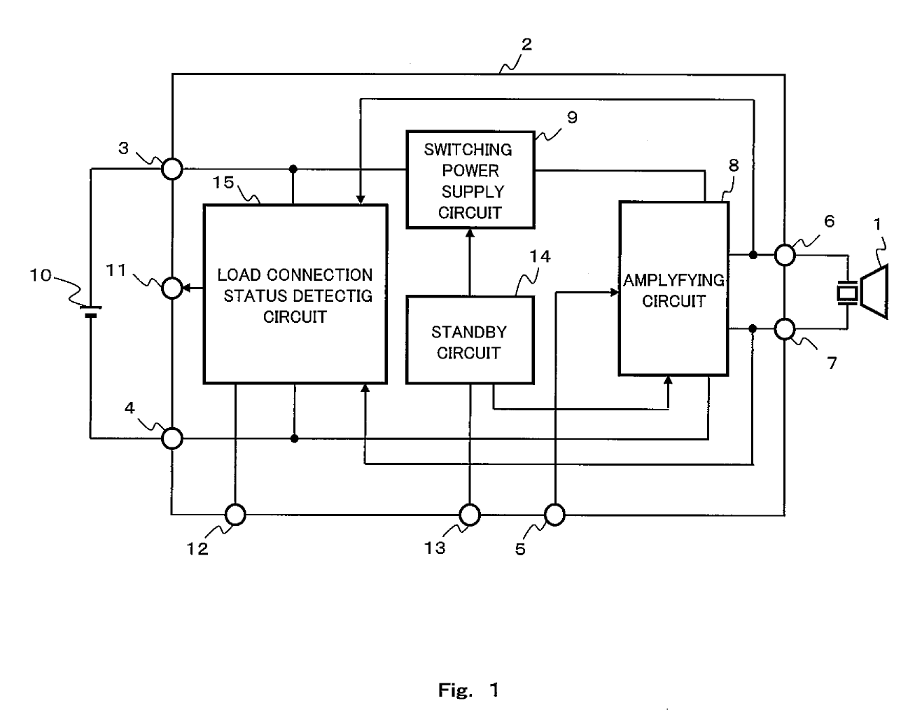

FIG. 1 is a diagram showing the configuration of a sound system using a speaker drive integrated circuit according to Embodiment 1 of the present invention. The sound system shown in FIG. 1 is one example of a mobile device with a speaker, such as a digital video camera, a digital still camera, a mobile phone, a notebook computer, or a fire alarm.

A speaker drive integrated circuit 2 operates using an external power supply 10, such as a lithium ion battery, as a power supply. The speaker drive integrated circuit 2 amplifies an audio signal input to an input terminal 5 to drive a speaker 1, such as a piezoelectric speaker. To realize such function, the speaker drive integrated circuit 2 includes an amplifying circuit 8, a switching power supply circuit 9, a standby circuit 14, and a load connection status detecting circuit 15. The speaker drive integrated circuit 2 includes, as its own terminals, a power supply terminal 3 and GND terminal 4 connected to the external power supply 10, the input terminal 5 to which the audio signal is input, a noninverted output terminal 6 connected to a positive terminal of the speaker 1, and an inverted output terminal 7 connected to a negative terminal of the speaker 1. Further, the speaker drive integrated circuit 2 includes a transmitting terminal 11 through which an output voltage V11 indicating a detection result of a load connection status is output to outside, a start-up terminal 12 to which a start-up voltage V12 for starting up the load connection status detecting circuit 15 is applied, and a standby terminal 13 to which a standby voltage V13 for setting a below-described standby state is applied.

The amplifying circuit 8 is configured to amplify the audio signal input to the input terminal 5 and adopts a so-called BTL (Bridged Trans Less) connection system. In accordance with the BTL connection system, respective outputs of two stereo amplifiers are bridge-connected, and an output voltage that is theoretically twice as high as a voltage of one stereo amplifier can be obtained. In addition, the amplifying circuit 8 can switch its own output to a high impedance state (electrically insulated state).

The switching power supply circuit 9 is configured to boost an input voltage (3 V, for example) supplied from the external power supply 10 to a boost voltage (6 to 30 V, for example) necessary for driving the speaker 1, based on a PWM (Pulse Width Modulation) system. The boost voltage generated in the switching power supply circuit 9 is supplied to the amplifying circuit 8.

The speaker 1 emits the sound by vibrations of a vibrator (such as a piezoelectric element) included in the speaker 1. The vibrator vibrates by the output voltage applied from the amplifying circuit 8 to both terminals of the vibrator.

When a standby voltage of any polarity is applied to the standby terminal 13, the standby circuit 14 switches each of the switching power supply circuit 9 and the amplifying circuit 8 from an operating state (on) to a nonoperating state (off) and switches each of the noninverted output terminal 6 and the inverted output terminal 7 from a normal operating state to the high impedance state (also referred to as a “mute state”).

By setting both the noninverted output terminal 6 and the inverted output terminal 7 to the high impedance state, a consumption current does not almost flow in the speaker drive integrated circuit 2 (except for the load connection status detecting circuit 15). Hereinafter, a state where the switching power supply circuit 9 and the amplifying circuit 8 are in the nonoperating state and both the noninverted output terminal 6 and the inverted output terminal 7 are in the high impedance state is referred to as a standby state.

In a case where the speaker drive integrated circuit 2 becomes the standby state by the application of the standby voltage to the standby terminal 13 and the start-up voltage V12 is applied to the start-up terminal 12, the load connection status detecting circuit 15 can detect the load connection status (normal, open, or short) of the speaker 1. Then, the load connection status detecting circuit 15 generates the output voltage V11 indicating the detection result of the load connection status of the speaker 1 and outputs the output voltage V11 through the transmitting terminal 11 to the outside.

Configuration of Speaker Drive Integrated Circuit

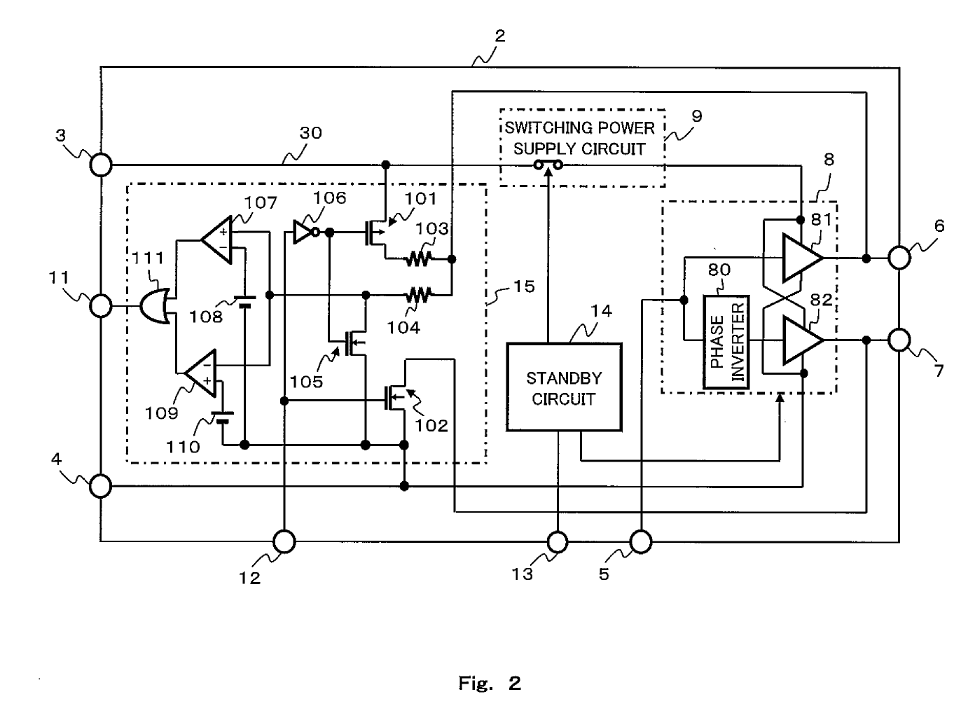

FIG. 2 is a diagram showing the configuration of the speaker drive integrated circuit 2 (especially, the load connection status detecting circuit 15) in Embodiment 1 of the present invention.

The amplifying circuit 8 includes an amplifier 81 (first amplifier in the present invention) configured to amplify the audio signal input to the input terminal 5, a phase inverter 80 configured to invert the phase of the audio signal, and an amplifier 82 (second amplifier in the present invention) configured to amplify the output of the phase inverter 80, based on the above-described BTL connection system. An output terminal of the amplifier 81 is connected to the noninverted output terminal 6, and an output terminal of the amplifier 82 is connected to the inverted output terminal 7. In a case where each of the amplifiers 81 and 82 is constituted by, for example, a difference amplifier, the high impedance state can be set by forcibly turn off an output transistor provided at an output stage of each of the amplifiers 81 and 82.

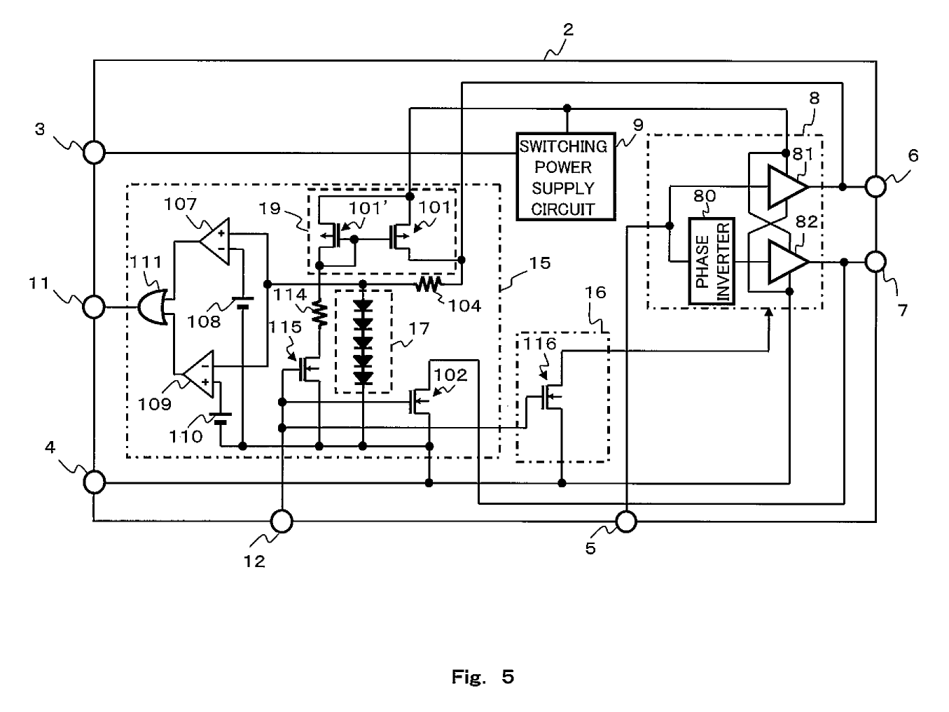

When the standby voltage is applied to the standby terminal 13, the standby circuit 14 outputs a signal for realizing the above-described standby state. For example, when the standby voltage is applied to a gate electrode, the standby circuit 14 stops the switching power supply circuit 9, and the supply of the boost voltage from the switching power supply circuit 9 to the amplifiers 81 and 82 directly stops. With this, the standby state is realized. Or, as with a switch circuit 16 shown in FIG. 5, the standby circuit 14 may include a NMOS transistor configured to be turned on when the standby voltage is applied to the gate electrode. When the NMOS transistor is turned on, the standby circuit 14 may forcibly turn off the output transistors provided at the output stages of the amplifiers 81 and 82.

The load connection status detecting circuit 15 includes a PMOS transistor 101 (first transistor in the present invention), a NMOS transistor 102 (second transistor in the present invention), and a NMOS transistor 105. A source electrode of the PMOS transistor 101 is connected to a power supply line 30 extending between the power supply terminal 3 and the switching power supply circuit 9, a drain electrode thereof is connected to the noninverted output terminal 6 via a current-limiting resistor 103, and a gate electrode thereof is connected to the start-up terminal 12 via a NOT gate 106. A drain electrode of the NMOS transistor 102 is connected to the inverted output terminal 7, a source electrode thereof is connected to the GND terminal 4, and a gate electrode thereof is connected to the start-up terminal 12. A drain electrode of the NMOS transistor 105 is connected to the noninverted output terminal 6 and the current-limiting resistor 103 via a current-limiting resistor 104, a source electrode thereof is connected to the GND terminal 4, and a gate electrode thereof is connected to the start-up terminal 12 via the NOT gate 106.

With this configuration, when the start-up voltage V12 of a high level is not applied to the start-up terminal 12, the NMOS transistor 105 is turned on, and the PMOS transistor 101 and the NMOS transistor 102 are turned off. With this, the noninverted output terminal 6 is shorted to a GND potential or a potential close to the GND potential via the current-limiting resistor 104 and the NMOS transistor 105, and the detection of the load connection status (normal, open, or short) by a below-described open detecting comparator 107 and short detecting comparator 109 based on the voltage V6 of the noninverted output terminal 6 becomes impossible. Conversely, in this case, the speaker 1 can be driven.

In contrast, when the start-up voltage V12 of the high level is applied to the start-up terminal 12, the PMOS transistor 101 and the NMOS transistor 102 are turned on, and the NMOS transistor 105 is turned off. With this, the noninverted output terminal 6 is connected to the power supply terminal 3 via the PMOS transistor 101 and the current-limiting resistor 103, and the inverted output terminal 7 is connected to the GND terminal 4 via the NMOS transistor 102. This realizes a circuit state where a current flows from the power supply terminal 3 through the PMOS transistor 101 and the current-limiting resistor 103 to the noninverted output terminal 6. As a result, the detection of the load connection status (normal, open, or short) based on the voltage V6 of the noninverted output terminal 6 by the below-described open detecting comparator 107 and short detecting comparator 109 is realized.

Further, the load connection status detecting circuit 15 includes the open detecting comparator 107 configured by using a difference amplifier, the short detecting comparator 109 configured by using a difference amplifier, a reference power supply 108 configured to generate an open threshold voltage V108, a reference power supply 110 configured to generate a short threshold voltage V110, and an OR gate 111. In the present embodiment, a noninverted input terminal of the open detecting comparator 107 and an inverted input terminal of the short detecting comparator 109 are connected to the noninverted output terminal 6 via the current-limiting resistor 104, an inverted input terminal of the open detecting comparator 107 is connected to a positive side of the reference power supply 108, and a noninverted input terminal of the short detecting comparator 109 is connected to a positive side of the reference power supply 110.

To be specific, the open detecting comparator 107 outputs a high-level voltage if the voltage V6 of the noninverted output terminal 6 (to be precise, a voltage between the other end of the current-limiting resistor 104 and the GND) is higher than the open threshold voltage V108 of the reference power supply 108 and outputs a low-level voltage if the voltage V6 is lower than the open threshold voltage V108 of the reference power supply 108. Therefore, the output of the high-level voltage by the open detecting comparator 107 means that the detected load connection status is “open”.

Moreover, the short detecting comparator 109 outputs the low-level voltage if the voltage V6 of the noninverted output terminal 6 is higher than the short threshold voltage V110 of the reference power supply 110 and outputs the high-level voltage if the voltage V6 is lower than the short threshold voltage V110 of the reference power supply 110. Therefore, the output of the high-level voltage by the short detecting comparator 109 means that the detected load connection status is “short”.

The OR gate 111 receives the outputs of the open detecting comparator 107 and short detecting comparator 109 and outputs a logical sum of those outputs through the transmitting terminal 11. Therefore, a case where the output voltage V11 of the OR gate 111 is the low-level voltage means that the speaker 1 is normally connected, and a case where the output voltage V11 of the OR gate 111 is the high-level voltage means that the detected connection status of the speaker 1 is open or short.

When the load connection status detecting circuit 15 is in the nonoperating state and the switching power supply circuit 9 and the amplifying circuit 8 are operating, the voltage V6 of the noninverted output terminal 6 dynamically changes in accordance with the voltage level of the audio signal and becomes the boost voltage of the switching power supply circuit 9 at most. For example, when the power supply terminal 3 is 3 V, the voltage V6 of the noninverted output terminal 6 becomes 6 to 30 V at most. Therefore, to prevent the voltage from exceeding a withstand voltage of an internal element of the load connection status detecting circuit 15, the following two protection measures are required.

As a first protection measure, the current-limiting resistor 104 (second current-limiting resistor in the present invention) and the NMOS transistor 105 (protection circuit in the present invention) are provided to protect the open detecting comparator 107 and the short detecting comparator 109 when the speaker 1 is operating (when the load connection status is not detected). More specifically, when the load connection status detecting circuit 15 is in the nonoperating state, the input terminal of each of the open detecting comparator 107 and the short detecting comparator 109 is shorted to the GND potential of the GND terminal 4 or a potential close to the GND potential via the NMOS transistor 105, and a current input to the open detecting comparator 107 and the short detecting comparator 109 is limited by the current-limiting resistor 104. The voltage of the input terminal of each of the open detecting comparator 107 and the short detecting comparator 109 may be a voltage equal to or lower than the withstand voltage of the input terminal, and the input terminal does not have to be shorted to the GND potential as above. Generally, since a gate withstand voltage of a transistor constituting the difference amplifier is lower than a drain withstand voltage thereof, the above measure is required.

As a second protection measure, the current-limiting resistor 103 (first current-limiting resistor in the present invention) is provided to protect the PMOS transistor 101 when the speaker 1 stops operating (when the load connection status is detected). More specifically, a current flowing through a signal line extending between the PMOS transistor 101 and the current-limiting resistor 103 is limited by a parasitic diode of the PMOS transistor 101 and the current-limiting resistor 103. Thus, the PMOS transistor 101 is prevented from being destroyed.

Timing Waveform Diagram of Load Connection Status Detecting Circuit

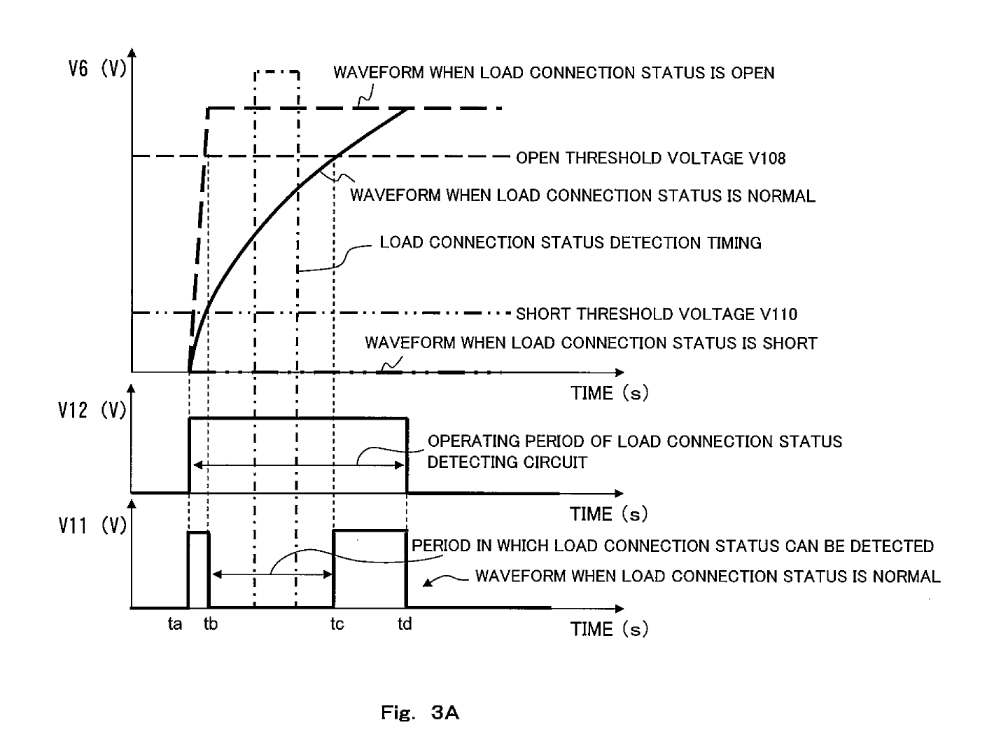

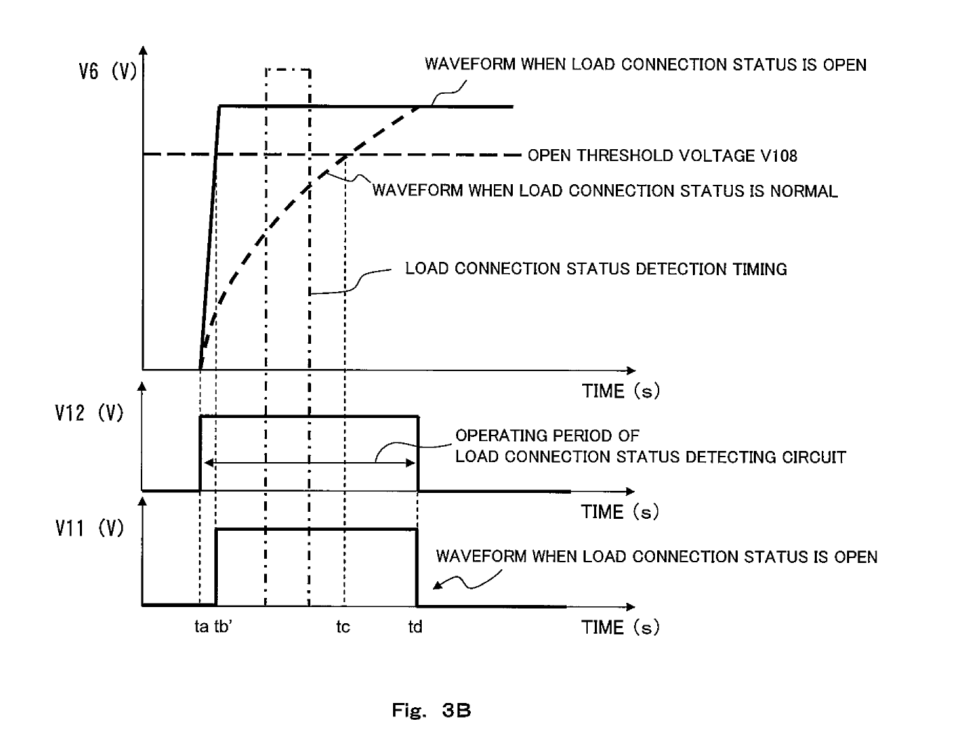

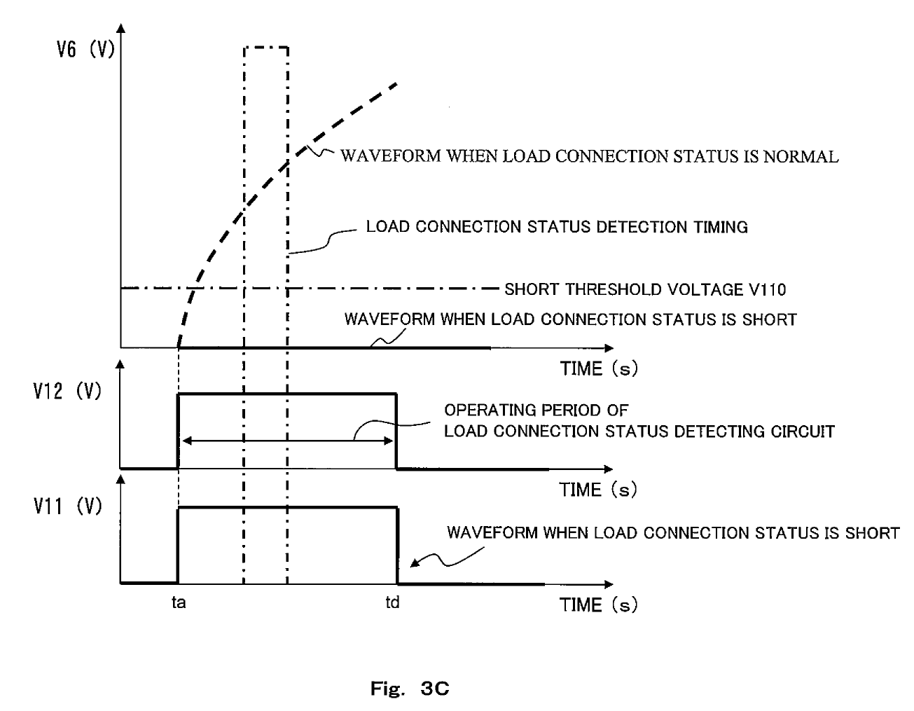

FIGS. 3A to 3C show examples of timing waveform diagrams of the load connection status detecting circuit 15. FIG. 3A shows a timing waveform diagram when the speaker 1, the noninverted output terminal 6, and the inverted output terminal 7 are normally connected to one another. FIG. 3B shows a timing waveform diagram when the noninverted output terminal 6 or the inverted output terminal 7 is open with respect to (is not connected to) the terminal of the speaker 1. FIG. 3C shows a timing waveform diagram when the speaker 1 itself is shorted or when the noninverted output terminal 6 and the inverted output terminal 7 are shorted by solder bridge or the like.

Hereinafter, a timing waveform of the load connection status detecting circuit 15 when the load connection status is normal as shown in FIG. 3A will be explained. In FIG. 3A, a time proceeds in order of time points ta, tb, tc, and td.

A period in which the start-up voltage V12 of the high level is applied to the start-up terminal 12, that is, a period from the time point ta until the time point td is an operating period of the load connection status detecting circuit 15. In the operating period of the load connection status detecting circuit 15 (from the time point ta to the time point td), a waveform trajectory of the voltage V6 of the noninverted output terminal 6 when the load connection status is normal is a moderately rising curve, and the voltage V6 is higher than the short threshold voltage V110 at the time point tb and is higher than the open threshold voltage V108 at the time point tc. This is because in a case where the speaker 1 is, for example, a piezoelectric speaker, the voltage V6 of the noninverted output terminal 6 when the load connection status is normal draws a charging curve for charging the capacity of a piezoelectric vibrator.

In a period from the time point ta until the time point tb, the voltage V6 of the noninverted output terminal 6 is lower than the open threshold voltage V108 and the short threshold voltage V110, the output of the short detecting comparator 109 is the high-level voltage, and the output of the open detecting comparator 107 is the low-level voltage. Therefore, the output voltage V11 of the load connection status detecting circuit 15 (to be precise, the OR gate 111) is the high-level voltage.

In a period from the time point tb until the time point tc, the voltage V6 of the noninverted output terminal 6 is within a range from the short threshold voltage V110 to the open threshold voltage V108, so that the output of each of the open detecting comparator 107 and the short detecting comparator 109 is the low-level voltage. Therefore, the output voltage V11 of the load connection status detecting circuit 15 is the low-level voltage.

In a period from the time point tc until the time point td, the voltage V6 of the noninverted output terminal 6 is higher than the short threshold voltage V110 and the open threshold voltage V108, so that the output of the short detecting comparator 109 is the low-level voltage, and the output of the open detecting comparator 107 is the high-level voltage. Therefore, the output voltage V11 of the load connection status detecting circuit 15 is the high-level voltage.

The above waveform of the output voltage V11 of the load connection status detecting circuit 15 from the time point ta to the time point td is a waveform when the load connection status is normal and is a waveform as a criteria for detecting whether the load connection status is open or short.

Next, a timing waveform of the load connection status detecting circuit 15 when the load connection status is open as shown in FIG. 3B will be explained. In FIG. 3B, a time proceeds in order of the time points ta, tb′, tc, and td, and the time points ta, tc, and td in FIG. 3B are the same in timing as those in FIG. 3A.

A period in which the start-up voltage V12 of the high level is applied to the start-up terminal 12, that is, a period from the time point ta until the time point td is the operating period of the load connection status detecting circuit 15. As compared to the voltage V6 when the load connection status is normal in FIG. 3A, the voltage V6 of the noninverted output terminal 6 when the load connection status is open draws an instantaneously rising waveform trajectory in the operating period of the load connection status detecting circuit 15 (from the time point ta to the time point td). The voltage V6 of the noninverted output terminal 6 immediately exceeds the short threshold voltage V110 (not shown) after the time point ta and is higher than the open threshold voltage V108 at the time point tb′. The time point tb′ is earlier than the time point tb.

In a period from the time point ta until the time point tb′, the voltage V6 of the noninverted output terminal 6 is higher than the short threshold voltage V110 and lower than the open threshold voltage V108, so that the output of each of the short detecting comparator 109 and the open detecting comparator 107 is the low-level voltage. Therefore, the output voltage V11 of the load connection status detecting circuit 15 is the low-level voltage.

In a period from the time point tb′ until the time point td, the voltage V6 of the noninverted output terminal 6 is higher than the short threshold voltage V110 and the open threshold voltage V108, so that the output of the short detecting comparator 109 is the low-level voltage, and the output of the open detecting comparator 107 is the high-level voltage. Therefore, the output voltage V11 of the load connection status detecting circuit 15 is the high-level voltage.

As above, the waveform of the output voltage V11 when the load connection status is open as shown in FIG. 3B is different from the waveform of the output voltage V11 when the load connection status is normal as shown in FIG. 3A in that the output voltage V11 when the load connection status is open becomes the low level in a short period (from the time point ta to the time point tb′) after the rising of the start-up voltage V12 and becomes the high level in the period (from the time point tb′ to the time point td) from after the above period until the falling of the start-up voltage V12. In other words, the waveform of the output voltage V11 when the load connection status is normal is apparently different from the waveform of the output voltage V11 when the load connection status is open in that the output voltage V11 when the load connection status is normal is the low level when the voltage V6 of the noninverted output terminal 6 is in a range from the short threshold voltage V110 to the open threshold voltage V108. Based on the difference between the waveform of the output voltage V11 when the load connection status is normal and the waveform of the output voltage V11 when the load connection status is open, it is possible to detect that the load connection status is open.

Next, the timing waveform of the load connection status detecting circuit 15 when the load connection status is short as shown in FIG. 3C will be explained. In FIG. 3C, a time proceeds in order of the time points ta and td, and the time points ta and td are the same in timing as those in FIG. 3A.

A period in which the start-up voltage V12 of the high level is applied to the start-up terminal 12, that is, a period from the time point ta until the time point td is the operating period of the load connection status detecting circuit 15. In the operating period of the load connection status detecting circuit 15 (from the time point ta to the time point td), the waveform of the voltage V6 of the noninverted output terminal 6 does not rise or exceed the short threshold voltage V110.

In a period from the time point ta until the time point td, the voltage V6 of the noninverted output terminal 6 is lower than the open threshold voltage V108 and the short threshold voltage V110, so that the output of the short detecting comparator 109 is the high-level voltage and the output of the open detecting comparator 107 is the low-level voltage. Therefore, the output voltage V11 of the load connection status detecting circuit 15 (to be precise, the OR gate 111) is the high-level voltage.

As above, the waveform of the output voltage V11 when the load connection status is short as shown in FIG. 3C is different from the waveform of the output voltage V11 when the load connection status is normal as shown in FIG. 3A in that the output voltage V11 when the load connection status is short becomes the high level in the period (from the time point tb to the time point td) after the rising of the start-up voltage V12 until the falling thereof. In other words, the waveform of the output voltage V11 when the load connection status is normal is apparently different from the waveform of the output voltage V11 when the load connection status is short in that the output voltage V11 when the load connection status is normal is the low level when the voltage V6 of the noninverted output terminal 6 is in a range from the short threshold voltage V110 to the open threshold voltage V108. Based on the difference between the waveform of the output voltage V11 when the load connection status is normal and the waveform of the output voltage V11 when the load connection status is short, it is possible to detect that the load connection status is short. In addition, the waveform of the output voltage V11 when the load connection status is short is different from the waveform of the output voltage V11 when the load connection status is open as shown in FIG. 3B in that the output voltage V11 when the load connection status is short becomes the high level immediately after the rising of the start-up voltage V12. Whether the load connection status is open or short can be detected based on the difference between the waveform when the load connection status is open and the waveform when the load connection status is short.

As above, in accordance with the present embodiment, the connection status (normal, open, or short) of the speaker 1 can be detected based on a characteristic change in the voltage V6 of the noninverted output terminal 6, the characteristic change corresponding to the connection status (normal, open, or short) of the speaker 1.

To surely detect whether the connection status of the speaker 1 is normal, open, or short, it is necessary to appropriately set a timing (hereinafter referred to as a “load connection status detection timing”) at which the change in the output voltage V11 corresponding to the connection status of the speaker 1 can be surely detected. The waveform diagram of the output voltage V11 when the connection status is normal as shown in FIG. 3A is different from the waveform diagram of the output voltage V11 when the connection status is open as shown in FIG. 3B and the waveform diagram of the output voltage V11 when the connection status is short as shown in FIG. 3C in that the output voltage V11 when the connection status is normal becomes the low level when the voltage V6 of the noninverted output terminal 6 is in a range from the short threshold voltage V110 to the open threshold voltage V108. The following will focus on this point. To be specific, the load connection status detection timing is set within a period (from the time point tb to the time point tc) in which the output voltage V11 when the connection status is normal as shown in FIG. 3A is the low level.

### Modification Example

The speaker drive integrated circuit 2 may be a hybrid integrated circuit constituted by replacing a part or all of the MOS transistors constituting the speaker drive integrated circuit 2 with bipolar transistors.

A NOR gate may be used instead of the OR gate 111. In this case, needless to say, the waveform of the output voltage V11 of the load connection status detecting circuit 15 shown in FIGS. 3A to 3C inverts.

A below-described clamp circuit 17 may be used instead of the NMOS transistor 105 as the protection circuit for the open detecting comparator 107 and the short detecting comparator 109.

The operating period of the load connection status detecting circuit 15 is set by applying the start-up voltage V12 of the high level to the start-up terminal 12 (active high) but may be set by applying the start-up voltage V12 of the low level to the start-up terminal 12 (active low).

The output voltage V11 of the load connection status detecting circuit 15 is output through the transmitting terminal 11 as a logical sum of the outputs of the open detecting comparator 107 and short detecting comparator 109. However, output terminals may be provided respectively for the outputs of the open detecting comparator 107 and short detecting comparator 109. With this, the user can easily recognize the detection of the open and/or the short by the load connection status detecting circuit 15.

Since the speaker 1 does not have the polarity, the positions of the noninverted output terminal 6 and inverted output terminal 7 shown in FIG. 1 may be switched.

As above, in accordance with Embodiment 1 of the present invention, in a state where the output of the amplifying circuit 8 is set to the high impedance state and the speaker 1 stops operating, an external power supply 19 for driving the speaker 1 can be effectively utilized (the voltage V6 for monitoring is generated by the external power supply 10), and the connection status (normal, open, or short) of the speaker 1 can be detected and transmitted to the outside. Moreover, the load connection status detecting circuit 15 for detecting the load connection status, the amplifying circuit 8, and the switching power supply circuit 9 are integrated in one IC, so that the mobile device on which the load connection status detecting circuit 15 is mounted can be reduced in size and weight.

Moreover, since the load connection status detecting circuit 15 can start up in accordance with the timing for detecting the load connection status, the power consumption of the entire integrated circuit when the speaker 1 stops operating can be suppressed.

Moreover, in the sound system of the present embodiment, the switching power supply circuit 9 does not start up in the standby state in addition to the amplifying circuit 8 (the switching power supply circuit 9 does not become the operating state). Therefore, the load connection status can be detected quickly due to the time necessary for the start-up of the switching power supply circuit 9.

Moreover, the mount area, cost, and the like can be reduced and the integration can be realized by a small number of parts, that is, two transistors (the PMOS transistor 101 and the NMOS transistor 102) and two comparators (the open detecting comparator 107 and the short detecting comparator 109). Thus, the mobile device on which the load connection status detecting circuit 15 is mounted can be reduced in size and weight.

Moreover, when driving the speaker 1 (when the start-up voltage V12 is not applied), the open detecting comparator and the short detecting comparator can be appropriately protected by the protection circuit (the NMOS transistor 105 and the like) and the current-limiting resistor 104. Moreover, when detecting the load connection status (when applying the start-up voltage V12), the PMOS transistor 101 can be appropriately protected by the parasitic diode of the PMOS transistor 101 and the current-limiting resistor 103.

### Embodiment 2

Configuration of Sound System

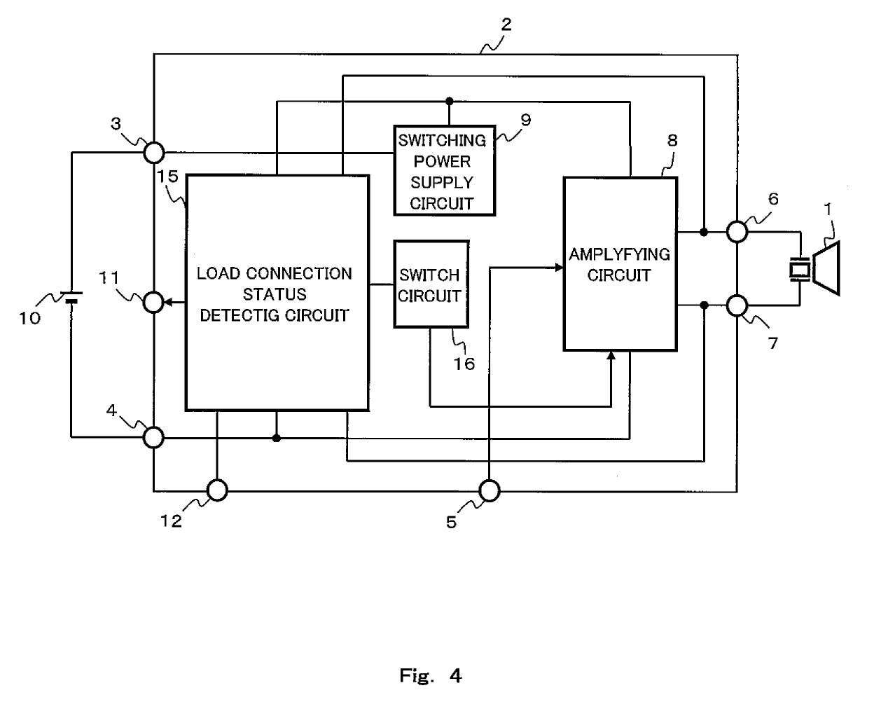

FIG. 4 is a diagram showing the configuration of the sound system using the speaker drive integrated circuit according to Embodiment 2 of the present invention.

The speaker drive integrated circuit 2 according to Embodiment 2 shown in FIG. 4 is different from the speaker drive integrated circuit 2 according to Embodiment 1 shown in FIG. 1 in that the standby terminal 13 and the standby circuit 14 are omitted, and the switch circuit 16 configured to realize the standby state is newly provided. The other components of the speaker drive integrated circuit 2 shown in FIG. 4 are the same as those of the speaker drive integrated circuit 2 shown in FIG. 1.

In the speaker drive integrated circuit 2 shown in FIG. 4, a terminal exclusively for the switch circuit 16 is not provided. The load connection status detecting circuit 15 and the switch circuit 16 share the start-up terminal 12. To be specific, when the start-up voltage V12 is applied to the start-up terminal 12, the switch circuit 16 sets such that the connection status (normal, open, or short) of the speaker 1 can be detected and switches the noninverted output terminal 6 and inverted output terminal 7 of the amplifying circuit 8 to the high impedance state. Details of the switch circuit 16 will be explained in the following explanation of the configuration of the speaker drive integrated circuit.

Configuration of Speaker Drive Integrated Circuit

FIG. 5 is a diagram showing the configuration of the speaker drive integrated circuit 2 (especially, the load connection status detecting circuit 15) according to Embodiment 2 of the present invention shown in FIG. 4.

The load connection status detecting circuit 15 in Embodiment 2 shown in FIG. 5 is different from the load connection status detecting circuit 15 in Embodiment 1 shown in FIG. 2 in that the NOT gate 106 is omitted, a current mirror circuit 19 constituted by PMOS transistors 101 and 101′ (a pair of first transistors in the present invention) having the same characteristics is provided, the NMOS transistor 105 is omitted, and a clamp circuit 17 is provided. Moreover, as above, in the speaker drive integrated circuit 2 according to Embodiment 2, the switch circuit 16 is newly provided. Hereinafter, these differences will be mainly explained.

The current mirror circuit 19 is constituted by the PMOS transistors 101 and 101′. The source electrode of the PMOS transistor 101 is connected to the output of the switching power supply circuit 9, the drain electrode thereof is connected to the noninverted output terminal 6, and the gate electrode thereof is connected to a gate electrode of the PMOS transistor 101′. A source electrode of the PMOS transistor 101′ is connected to the output of the switching power supply circuit 9, and a drain electrode thereof is connected to the GND terminal 4. Moreover, the gate electrode and drain electrode of the PMOS transistor 101′ are diode-connected (short-circuited).

A current-limiting resistor 114 and a NMOS transistor 115 are provided between the drain electrode of the PMOS transistor 101′ and the GND terminal 4. A gate electrode of the NMOS transistor 115 is connected to the start-up terminal 12. The NMOS transistor 115 is turned on when the start-up voltage V12 of the high level is applied to the start-up terminal 12. As with FIG. 2, the start-up terminal 12 is also connected to the NMOS transistor 102.

With the above configuration, the current mirror circuit 19 operates using the boost voltage of the switching power supply circuit 9 as the power supply when the NMOS transistor 115 is on. The current mirror circuit 19 operates such that a source current of the PMOS transistor 101′ and a source current of the PMOS transistor 101 become substantially equal to each other.

The clamp circuit 17 clamps the input of each of the open detecting comparator 107 and the short detecting comparator 109 to a withstand voltage thereof or lower. The clamp circuit 17 is provided instead of the NMOS transistor 105 shown in FIG. 2. As with the position of the NMOS transistor 105, the clamp circuit 17 is provided between the noninverted output terminal 6 and the GND terminal 4 via the current-limiting resistor 104. In the example shown in FIG. 5, the clamp circuit 17 is constituted by serially connecting a plurality of diodes. The clamp circuit 17 clamps the input of each of the open detecting comparator 107 and the short detecting comparator 109 to a total voltage of respective forward voltages of the plurality of diodes. Of course, the clamp circuit 17 is not limited to the above configuration using the plurality of diodes. For example, the clamp circuit 17 may be configured by serially connecting a plurality of diode-connected transistors.

When the start-up voltage V12 of the high level is applied to the start-up terminal 12, the switch circuit 16 switches the noninverted output terminal 6 and the inverted output terminal 7 of the amplifying circuit 8 from a normal state to the high impedance state. In the example shown in FIG. 5, the switch circuit 16 is constituted by a NMOS transistor 116. A drain electrode of the NMOS transistor 116 is connected to the amplifying circuit 8, a source electrode thereof is connected to the GND terminal 4, and a gate electrode thereof is connected to the start-up terminal 12. Therefore, when the start-up voltage of the high level is applied to the start-up terminal 12, the NMOS transistor 116 is turned on, and the transistors of output stages of the amplifiers 81 and 82 are turned off. Thus, the noninverted output terminal 6 and the inverted output terminal 7 are switched from the normal state to the high impedance state.

Operations of Load Connection Status Detecting Circuit

When the start-up voltage V12 is not applied to the start-up terminal 12, the current mirror circuit 19 does not operate. Therefore, the PMOS transistor 101 is turned off, and the NMOS transistor 102 and the NMOS transistor 105 are also turned off. With this, the noninverted output terminal 6 is shorted to a voltage close to the GND potential via the current-limiting resistor 104 and the clamp circuit 17. Thus, the detection of the load connection status (normal, open, or short) based on the voltage V6 of the noninverted output terminal 6 by the open detecting comparator 107 and the short detecting comparator 109 cannot be carried out. Conversely, in this case, the speaker 1 can operate.

In contrast, when the start-up voltage V12 is applied to the start-up terminal 12, the PMOS transistor 101 is turned on in accordance with the operation of the current mirror circuit 19, and the NMOS transistor 102 and the NMOS transistor 115 are also turned on. With this, the noninverted output terminal 6 is connected to the output of the switching power supply circuit 9 via the PMOS transistor 101, and the inverted output terminal 7 is connected to the GND terminal 4 via the NMOS transistor 102. Moreover, in accordance with the turn-on of the NMOS transistor 115, the current mirror circuit 19 operates using the switching power supply circuit 9 as the power supply. This realizes a circuit state where a current flows from the switching power supply circuit 9 through the PMOS transistor 101 to the noninverted output terminal 6. The current flowing to the noninverted output terminal 6 is limited by the current-limiting resistor 114 and the NMOS transistor 115. As a result, the detection of the load connection status (normal, open, or short) based on the voltage V6 of the noninverted output terminal 6 by the open detecting comparator 107 and the short detecting comparator 109 can be realized.

The timing waveform diagram of the load connection status detecting circuit 15 in Embodiment 2 is the same as the timing waveform diagram (FIGS. 3A, 3B, and 3C) of the load connection status detecting circuit 15 in Embodiment 1, so that an explanation thereof is omitted. In Embodiment 2, the same modification example as Embodiment 1 may be possible.

As above, in accordance with Embodiment 2 of the present invention, the same effects as Embodiment 1 of the present invention can be obtained. For example, the mount area, cost, and the like can be reduced and the integration can be realized by a small number of parts, that is, the current mirror circuit 19, one transistor (the NMOS transistor 102), and two comparators (the open detecting comparator 107 and the short detecting comparator 109). Thus, the mobile device on which the load connection status detecting circuit 15 is mounted can be reduced in size and weight.

Moreover, the start-up terminal 12 can function as both an input terminal to which an external command (start-up voltage) for starting up the load connection status detecting circuit 15 is input and an input terminal to which an external command (standby voltage) for setting the output of the amplifying circuit to the high impedance state is input. With this, the speaker drive integrated circuit 2 can be further reduced in size.

Moreover, when driving the speaker 1 (when the start-up voltage V12 is not applied), the open detecting comparator 107 and the short detecting comparator 109 can be appropriately protected by the protection circuit (clamp circuit 17) and the current-limiting resistor 104 (second current-limiting resistor). Moreover, when detecting the load connection status (when applying the start-up voltage V12), the current mirror circuit 19 can be appropriately protected by the current-limiting resistor 114 (first current-limiting resistor).

### Embodiment 3

Configuration of Sound System

The configuration of the sound system using the speaker drive integrated circuit according to Embodiment 3 of the present invention is the same as the configuration (FIG. 4) of the sound system in Embodiment 2 of the present invention, so that an explanation thereof is omitted.

Configuration of Speaker Drive Integrated Circuit

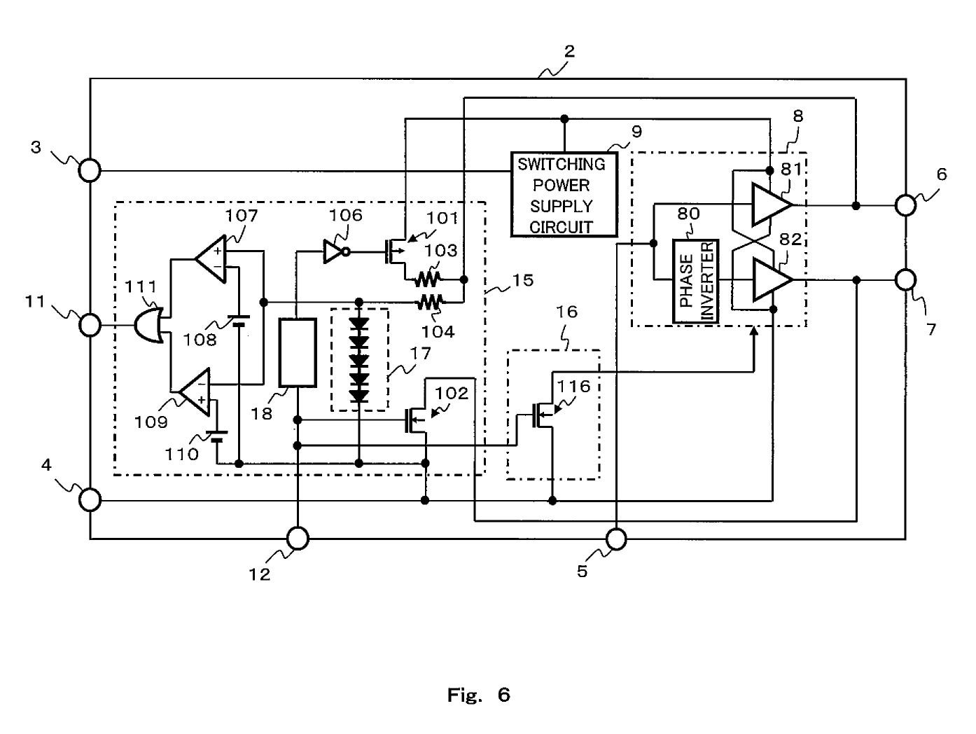

FIG. 6 is a diagram showing the configuration of the speaker drive integrated circuit 2 (especially, the load connection status detecting circuit 15) according to Embodiment 3 of the present invention.

The speaker drive integrated circuit 2 according to Embodiment 3 shown in FIG. 6 is configured based on the speaker drive integrated circuit 2 according to Embodiment 2 shown in FIG. 5. The speaker drive integrated circuit 2 according to Embodiment 3 is different from the speaker drive integrated circuit 2 according to Embodiment 2 in that: the current mirror circuit 19 shown in FIG. 5 is omitted; and when the start-up voltage V12 of the high level is applied to the start-up terminal 12, a current flows from the switching power supply circuit 9 through the PMOS transistor 101 and the current-limiting resistor 103 to the noninverted output terminal 6. In addition, the NOT gate 106 is provided to drive the gate electrode of the PMOS transistor 101. To be specific, the source electrode of the PMOS transistor 101 is connected to the output of the switching power supply circuit 9, the drain electrode thereof is connected to the noninverted output terminal 6 via the current-limiting resistor 103, and the gate electrode thereof is connected to the start-up terminal 12 via the NOT gate 106.

Moreover, in the speaker drive integrated circuit 2 according to Embodiment 3, a level-shift circuit 18 is provided between the NOT gate 106 and the start-up terminal 12 to protect the PMOS transistor 101. The level-shift circuit 18 carries out level shift such that the gate voltage of the PMOS transistor 101 becomes a predetermined potential when driving the PMOS transistor 101. With this, the PMOS transistor 101 is protected.

Operations of Load Connection Status Detecting Circuit

The operations of the load connection status detecting circuit 15 in Embodiment 3 are the same as those of the load connection status detecting circuit 15 in Embodiment 2, so that explanations thereof are omitted. In addition, the timing waveform diagram of the load connection status detecting circuit 15 in Embodiment 3 is the same as the timing waveform diagram (FIGS. 3A, 3B, and 3C) of the load connection status detecting circuit 15 in Embodiment 1, so that an explanation thereof is omitted. In Embodiment 3, the same modification example as Embodiment 1 may be possible.

As above, in accordance with Embodiment 3 of the present invention, the same effects as Embodiment 1 of the present invention can be obtained. For example, the mount area, cost, and the like can be reduced and the integration can be realized by a small number of parts, that is, two transistors (the PMOS transistor 101 and the NMOS transistor 102) and two comparators (the open detecting comparator 107 and the short detecting comparator 109). Thus, the mobile device on which the load connection status detecting circuit 15 is mounted can be reduced in size and weight.

Moreover, when driving the speaker 1 (when the start-up voltage V12 is not applied), the open detecting comparator 107 and the short detecting comparator 109 can be appropriately protected by the protection circuit (the clamp circuit 17 and the like) and the current-limiting resistor 104 (second current-limiting resistor). Moreover, when detecting the load connection status (when applying the start-up voltage V12), the PMOS transistor 101 can be appropriately protected by the parasitic diode of the PMOS transistor 101 and the current-limiting resistor 103.

The foregoing has exemplified a case where the vibrator (electricity/sound conversion element) of the speaker 1 is a capacitive element. However, in a case where the vibrator of the speaker 1 is an inductive element (such as a magnetostrictive vibrator), the load connection status (normal, open, or short) can be detected by detecting the current flowing through the noninverted output terminal 6. In this case, the current draws a rising curve when the load connection status is normal, the current does not flow when the load connection status is open, and a short-circuit current flows when the load connection status is short.

From the foregoing explanation, many modifications and other embodiments of the present invention are obvious to one skilled in the art. Therefore, the foregoing explanation should be interpreted only as an example and is provided for the purpose of teaching the best mode for carrying out the present invention to one skilled in the art. The structures and/or functional details may be substantially modified within the spirit of the present invention.

The present invention detects the connection status (normal, open, or short) of the speaker and transmits the connection status to the outside. The present invention is useful for the speaker drive integrated circuit mounted on the mobile device which is reduced in size and weight.

What is claimed is:

1. A speaker drive integrated circuit comprising:
a power supply terminal and a GND terminal, each connected to an external power supply;
an input terminal to which an audio signal is input;
two output terminals respectively connected to both ends of a speaker;
an amplifying circuit including a first amplifier and a second amplifier and capable of setting an output side thereof to a high impedance state during a non-operating period, the first amplifier being configured to amplify the audio signal input to the input terminal and output the amplified audio signal through one of said two output terminals, the second amplifier being configured to invert a phase of the audio signal, amplify the phase-inverted audio signal, and output the amplified audio signal through the other output terminal;
a switching power supply circuit configured to boost a voltage of the external power supply connected to the power supply terminal and the GND terminal such that an output of the amplifying circuit becomes a predetermined voltage necessary for driving the speaker;
a standby circuit configured to selectively set the amplifying circuit between an operating state and a nonoperating state where the output side is in the high impedance state;
a load connection status detecting circuit configured to cause a current to flow from the external power supply to one of said two output terminals when the standby circuit sets the amplifying circuit to the nonoperating state where the output side is in the high impedance state and detect whether a load connection status of the speaker with respect to said two output terminals is normal, open, or short based on a voltage generated at said one of said two output terminals by the current; and
a transmitting terminal through which a signal indicating a detection result by the load connection status detecting circuit is output to outside.

2. The speaker drive integrated circuit according to claim 1, further comprising:
a standby terminal to which a standby voltage is applied, the standby voltage specifying the nonoperating state of the amplifying circuit with respect to the standby circuit; and
a start-up terminal to which a start-up voltage is applied, the start-up voltage causing the load connection status detecting circuit to start up, wherein
when the start-up voltage is applied to the start-up terminal, the load connection status detecting circuit causes a current to flow from the external power supply to one of said two output terminals to start detecting the load connection status.

3. The speaker drive integrated circuit according to claim 1, further comprising:
a start-up terminal to which a start-up voltage is applied, the start-up voltage causing the load connection status detecting circuit to start up, wherein
when the start-up voltage is applied to the start-up terminal, the load connection status detecting circuit sets the output side of the amplifying circuit to the high impedance state and causes a current to flow from the external power supply to one of said two output terminals to start detecting the load connection status.

4. The speaker drive integrated circuit according to claim 3, wherein the load connection status detecting circuit includes:
a first transistor provided between the power supply terminal and one of said two output terminals and configured to be turned on when the start-up voltage is applied to the start-up terminal;
a second transistor provided between the other output terminal and the GND terminal and configured to be turned on when the start-up voltage is applied to the start-up terminal;
an open detecting comparator configured to compare a voltage of said one of said two output terminals with an open threshold voltage and detect that the load connection status is open if the voltage of said one of said two output terminals is higher than the open threshold voltage in a predetermined period after the start-up voltage is applied to the start-up terminal; and
a short detecting comparator configured to compare the voltage of said one of said two output terminals with a short threshold voltage and detect that the load connection status is short if the voltage of said one of said two output terminals is lower than the short threshold voltage in the predetermined period after the start-up voltage is applied to the start-up terminal.

5. The speaker drive integrated circuit according to claim 4, further comprising:
a first current-limiting resistor configured to limit a current when the start-up voltage is applied to the start-up terminal, the current flowing through the first transistor;
a protection circuit configured to short or clamp each of inputs of the open detecting comparator and short detecting comparator to GND or a potential equal to or lower than a withstand voltage of the input when the start-up voltage is not applied to the start-up terminal, the open detecting comparator and the short detecting comparator being supplied with the voltage of said one of said two output terminals; and
a second current-limiting resistor configured to limit a current when the start-up voltage is not applied to the start-up terminal, the current flowing to the inputs of the open detecting comparator and short detecting comparator.

6. The speaker drive integrated circuit according to claim 3, wherein the load connection status detecting circuit includes:
a current mirror circuit configured by a pair of first transistors to cause a current to flow from the switching power supply to one of said two output terminals when the start-up voltage is applied to the start-up terminal;
a second transistor provided between the other output terminal and the GND terminal and configured to be turned on when the start-up voltage is applied to the start-up terminal;
an open detecting comparator configured to compare a voltage of said one of said two output terminals with an open threshold voltage and detect that the load connection status is open if the voltage of said one of said two output terminals is higher than the open threshold voltage in a predetermined period after the start-up voltage is applied to the start-up terminal; and
a short detecting comparator configured to compare the voltage of said one of said two output terminals with a short threshold voltage and detect that the load connection status is short if the voltage of said one of said two output terminals is lower than the short threshold voltage in the predetermined period after the start-up voltage is applied to the start-up terminal.

7. The speaker drive integrated circuit according to claim 6, further comprising:
a protection circuit configured to short or clamp each of inputs of the open detecting comparator and short detecting comparator to GND or a potential equal to or lower than a withstand voltage of the input when the start-up voltage is not applied to the start-up terminal, the open detecting comparator and the short detecting comparator being supplied with the voltage of said one of said two output terminals;
a first current-limiting resistor configured to limit a current when the start-up voltage is not applied to the start-up terminal, the current flowing to the inputs of the open detecting comparator and short detecting comparator; and
a second current-limiting resistor configured to limit a current when the start-up voltage is applied to the start-up terminal, the current flowing through the current mirror circuit.

8. The speaker drive integrated circuit according to claim 3, wherein the load connection status detecting circuit includes:
a first transistor provided between an output of the switching power supply circuit and one of said two output terminals and configured to be turned on when the start-up voltage is applied to the start-up terminal;
a second transistor provided between the other output terminal and the GND terminal and configured to be turned on when the start-up voltage is applied to the start-up terminal;
an open detecting comparator configured to compare a voltage of said one of said two output terminals with an open threshold voltage and detect that the load connection status is open if the voltage of said one of said two output terminals is higher than the open threshold voltage in a predetermined period after the start-up voltage is applied to the start-up terminal; and
a short detecting comparator configured to compare the voltage of said one of said two output terminals with a short threshold voltage and detect that the load connection status is short if the voltage of said one of said two output terminals is lower than the short threshold voltage in the predetermined period after the start-up voltage is applied to the start-up terminal.

9. The speaker drive integrated circuit according to claim 8, further comprising:
a first current-limiting resistor configured to limit a current when the start-up voltage is applied to the start-up terminal, the current flowing through the first transistor;
a protection circuit configured to short or clamp each of inputs of the open detecting comparator and short detecting comparator to GND or a potential equal to or lower than a withstand voltage of the input when the start-up voltage is not applied to the start-up terminal, the open detecting comparator and the short detecting comparator being supplied with the voltage of said one of said two output terminals;
a second current-limiting resistor configured to limit a current when the start-up voltage is not applied to the start-up terminal, the current flowing to the inputs of the open detecting comparator and short detecting comparator; and
a level-shift circuit configured to carry out level shift such that a control voltage applied to a control electrode of the first transistor becomes a predetermined potential.
